(19) United States
(12) Patent Application Publication
(10) Pub. No.: US 2020/0105453 A1
(43) Pub. Date: Apr. 2, 2020

(54) INKJET PRINTED ELECTRONIC COMPONENTS

(71) Applicant: TEXAS INSTRUMENTS INCORPORATED, Dallas, CA (US)

(72) Inventors: Yi YAN, Sunnyvale, CA (US); Luu Thanh NGUYEN, San Jose, CA (US); Ashok PRABHU, San Jose, CA (US); Anindya PODDAR, Sunnyvale, CA (US)

(21) Appl. No.: 16/148,981

(22) Filed: Oct. 1, 2018

(51) Int. Cl. H01F 27/28; H01F 27/29; H01F 41/04; H01F 27/32

(52) U.S. Cl. CPC H01F 27/2804; H01F 27/29; H01L 28/10; H01F 27/323; H01F 2027/2809; H01F 41/043

(57) ABSTRACT

In examples, a device includes a plurality of magnetic layers comprising magnetic ink residue; and a plurality of metallic layers comprising metallic ink residue and coupled to the plurality of magnetic layers, the plurality of metallic layers coupled to each other to form a coil.

### SUMMARY

In examples, a device includes a plurality of magnetic layers comprising magnetic ink residue; and a plurality of metallic layers comprising metallic ink residue and coupled to the plurality of magnetic layers, the plurality of metallic layers coupled to each other to form a coil.

In examples, a method of fabricating a device comprises inkjet printing a first magnetic layer using magnetic ink; inkjet printing a first metallic layer using metallic ink, the first magnetic and metallic layers abutting each other; inkjet printing a second magnetic layer using the magnetic ink, the first and second magnetic layers abutting each other; and inkjet printing a second metallic layer using the metallic ink, the first and second metallic layers abutting each other, and the second magnetic and metallic layers abutting each other. The first and second metallic layers form at least part of a coil.

In examples, a device comprises a collection of magnetic ink residue; and a coil encased within the collection of magnetic ink residue and comprising metallic ink residue, a first terminal of the coil exposed on a first surface of the collection of magnetic ink residue and a second terminal of the coil exposed on a second surface of the collection of magnetic ink residue.

### BRIEF DESCRIPTION OF THE DRAWINGS

For a detailed description of various examples, reference will now be made to the accompanying drawings in which:

FIG. 1 depicts an example of an inkjet printing system;

FIGS. 2A-2L depict the manufacture of an inkjet-printed coil device in a top-down view and in accordance with various examples;

FIGS. 3A-3L depict the manufacture of an inkjet-printed coil device in a modified side view and in accordance with various examples;

FIGS. 4A-4B depict multiple perspective views of an inkjet-printed coil device in accordance with various examples;

FIG. 5 depicts a method of manufacturing an inkjet-printed coil device in accordance with various examples; and

FIG. 6 depicts an inkjet-printed coil device mounted on an integrated circuit in a package.

### DETAILED DESCRIPTION

Various types of electronic components, such as inductor coils, are fabricated using a multi-step process that involves the use of a variety of fabrication materials. For example, inductor coils are fabricated using a series of specialized masks. The use of such fabrication materials is tedious, time-consuming, inefficient, and expensive.

In an example of the present disclosure, an inkjet-printed coil device includes a plurality of magnetic layers comprising magnetic ink residue, and a plurality of metallic layers comprising metallic ink residue and coupled to the plurality of magnetic layers. The plurality of metallic layers are coupled to each other to form a coil—for example, a coil usable in an inductor application. The magnetic and metallic layers are formed using an additive manufacturing process—specifically, inkjet printing. Such inkjet-printed devices remediate the challenges described above because they eliminate the need to use various fabrication materials (e.g., masks). Moreover, as described below, the properties of the magnetic and metallic inks may be customized to produce inductors/transformers with specific qualities and operational parameters. For example, the magnetic ink may have different particle sizes and shapes to tailor the magnetic properties of the inductor or transformer as desired.

The description and drawings that follow primarily illustrate the fabrication of transformer (or inductor) coils using inkjet printing. The scope of this disclosure, however, is not limited to the fabrication of coils or the use of inkjet printing. Other electronic components suitable for fabrication using inkjet printing, or any other appropriate additive manufacturing technique(s) other than inkjet printing, are contemplated and included within the scope of this disclosure. In addition, the term “magnetic ink” may be used interchangeably herein in certain contexts with the term “magnetic layer.” Similarly, the term “metallic ink” may be used interchangeably in certain contexts herein with the term “metallic layer.” The term “magnetic ink residue” refers to magnetic ink that has been deposited and dried (or post-processed, for example, by co-firing). Similarly, the term “metallic ink residue” refers to metallic ink that has been deposited and dried (or post-processed, for example, by co-firing). With respect to “magnetic ink residue” and “metallic ink residue,” co-firing entails placing the inkjet-printed electronic component in a furnace. The temperature of the furnace is then increased to a level suitable for sintering, for example, to several hundred degrees Celsius. In some examples, the temperature has a maximum of approximately 960 degrees Celsius. The inkjet-printed electronic component may be sintered for a few hours (e.g., between one and five hours), and in a specific example, for two hours. The specific amount of sintering time may depend on a variety of factors, such as sintering temperature, number of components being sintered, volume of the furnace, etc. Post-polish and/or plasma cleaning also may be performed as part of post-processing. For example, if the surfaces of the electronic component are not satisfactorily smooth after sintering, or if they contain organic residues, polishing or plasma cleaning techniques may be used to smooth and clean the surfaces. In examples, such polishing or cleaning is performed manually by humans, although automatic machine polishing and cleaning is contemplated and included in the scope of this disclosure. A “coil portion” is a metallic layer.

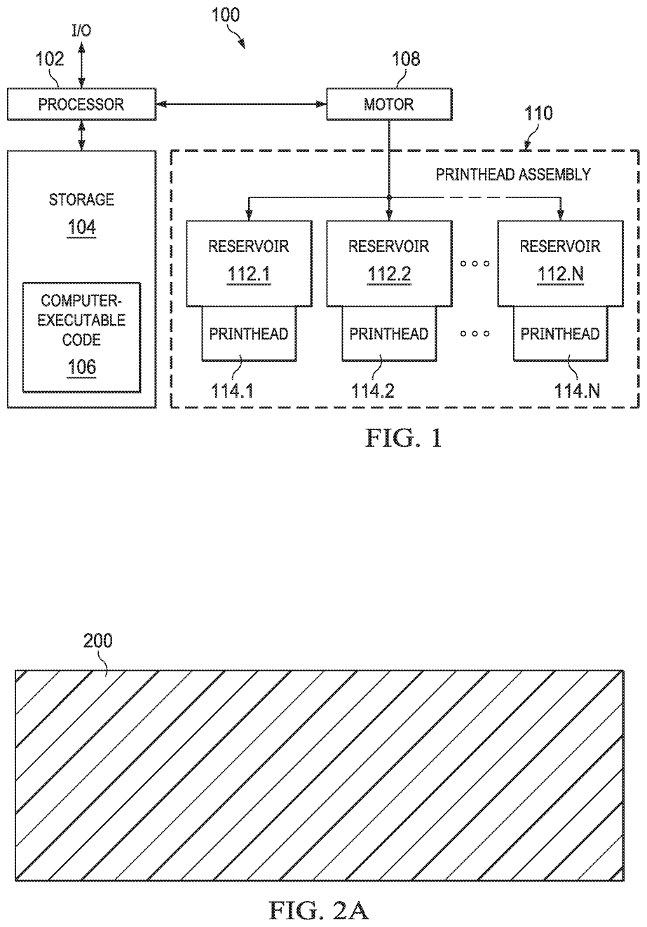

FIG. 1 depicts an example of an inkjet printing system 100. The inkjet printing system 100 includes a processor 102; storage 104 (e.g., random access memory (RAM), read-only memory (ROM)) coupled to the processor 102; computer-executable code 106 stored in the storage 104; and a motor 108 coupled to and controlled by the processor 102, for example, as a result of the processor 102 executing the computer-executable code 106. In addition, the system 100 comprises a printhead assembly 110. The printhead assembly 110 includes a plurality of reservoirs 112.1, 112.2, . . . , 112.N coupled to the motor 108. The reservoirs may collectively be referred to as reservoirs 112, and they may store one or more of magnetic ink, metallic ink, and/or polymer ink, as described below. One or more of the reservoirs 112 couples to a respective printhead 114 (e.g., reservoirs 112.1, 112.2, . . . , 112.N may couple to printheads 114.1, 114.2, . . . , 114.N, respectively). In an example, the processor 102, upon executing the computer-executable code 106, controls the motor 108, which, in turn, controls the reservoirs 112 and the printheads 114 to manufacture devices (e.g., transformer/inductor coils) using inkjet printing techniques. The scope of this disclosure is not limited to inkjet printing systems with the particular configuration shown in FIG. 1. Other configurations and additive manufacturing systems are contemplated and included in the scope of this disclosure.

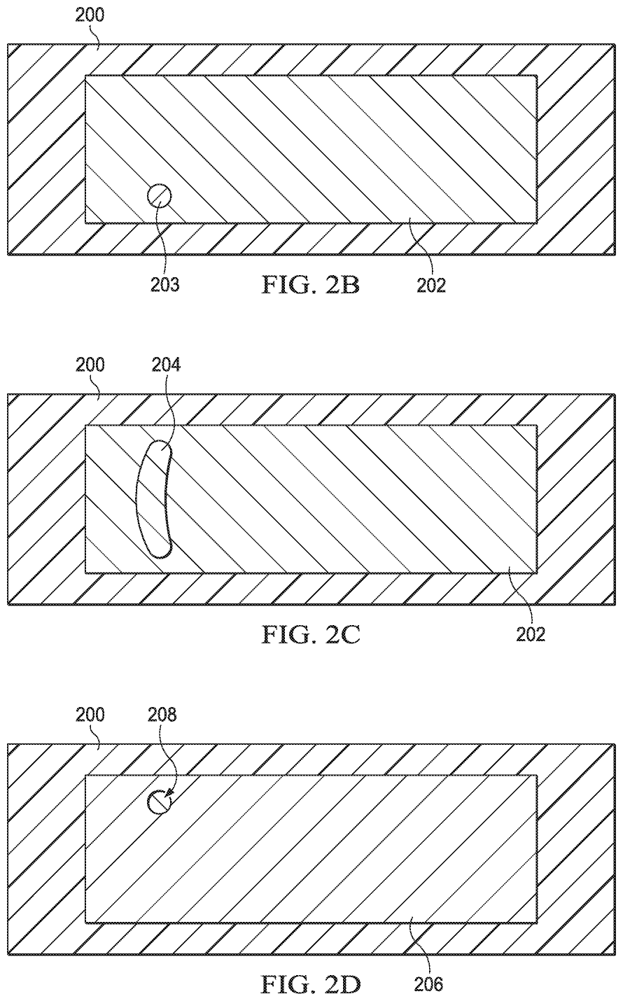

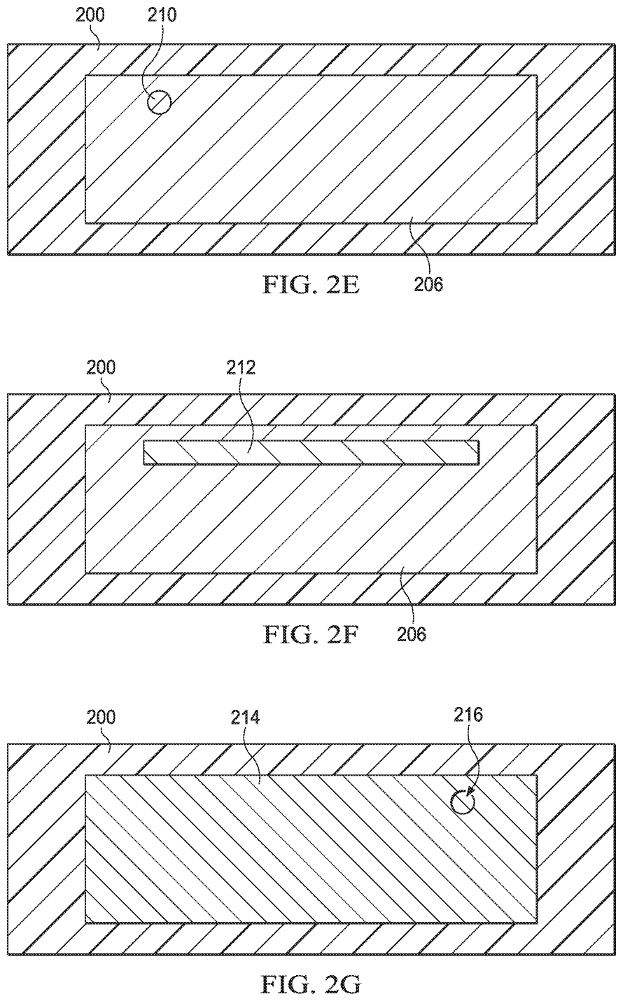

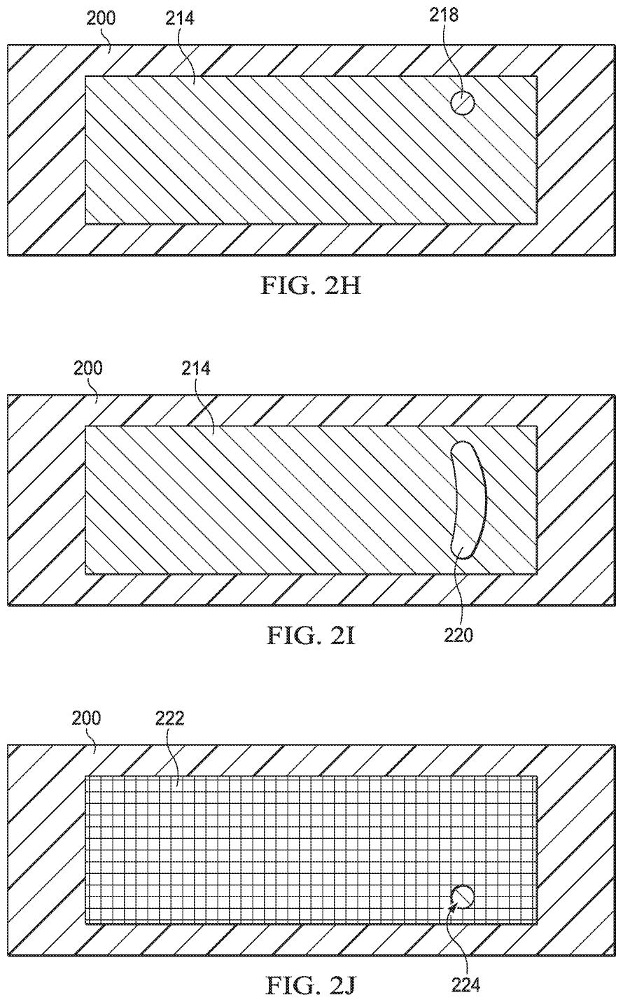

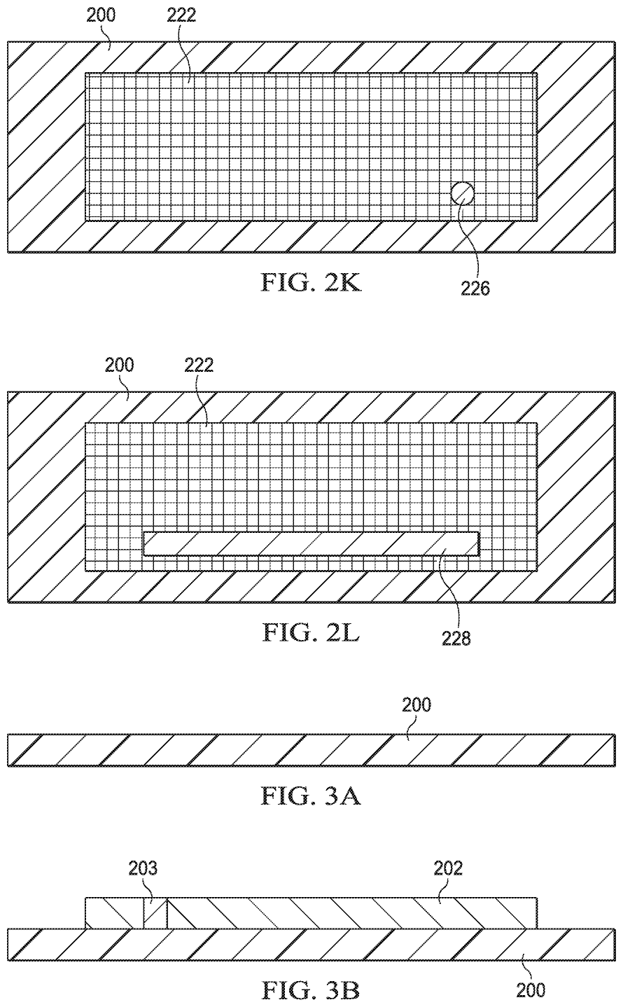

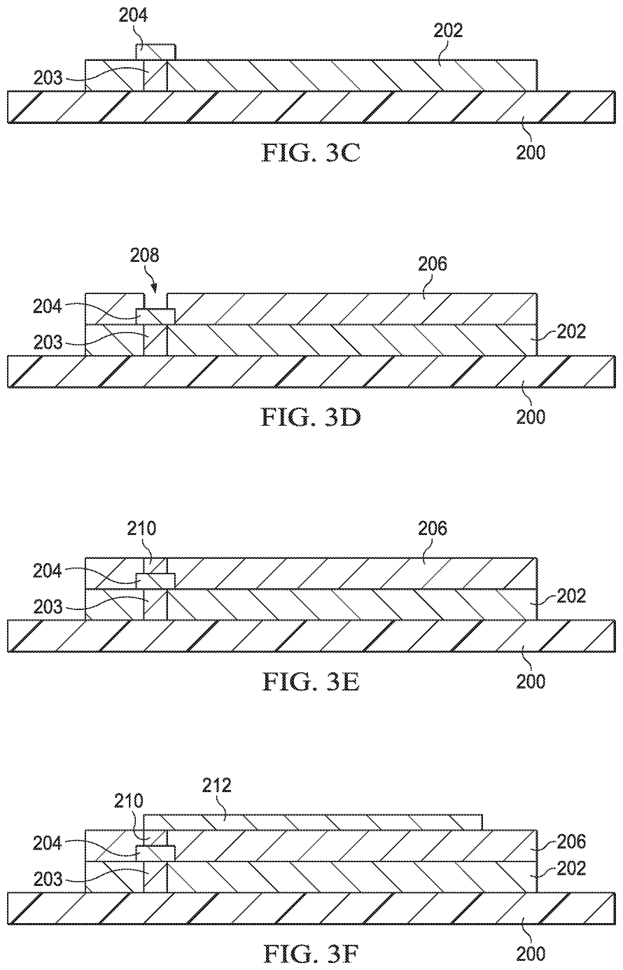

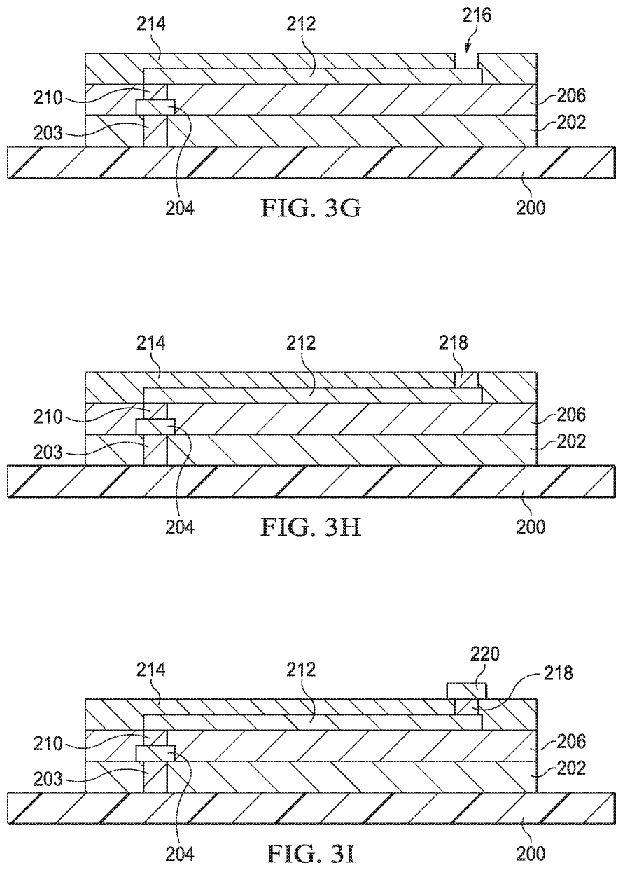

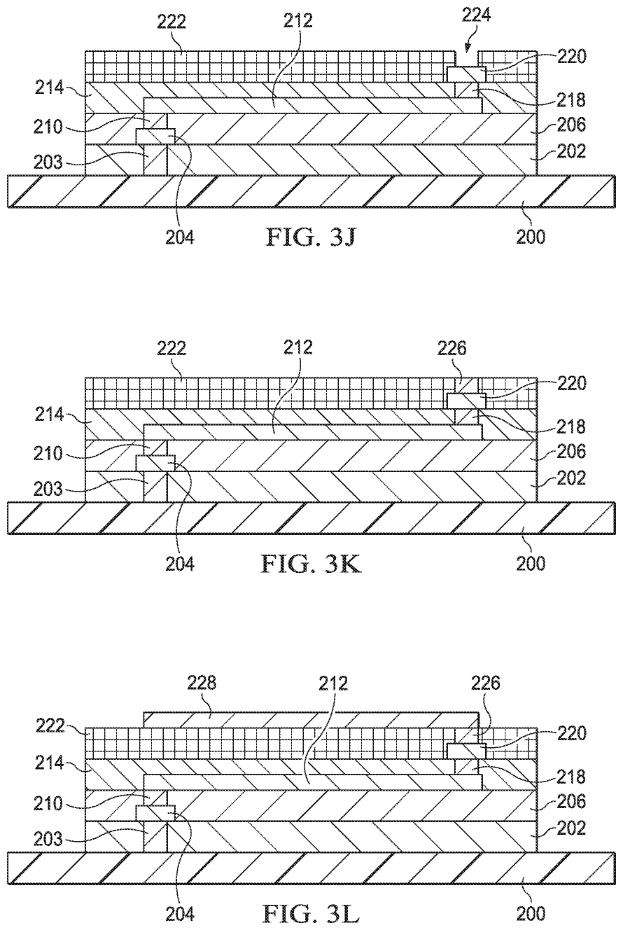

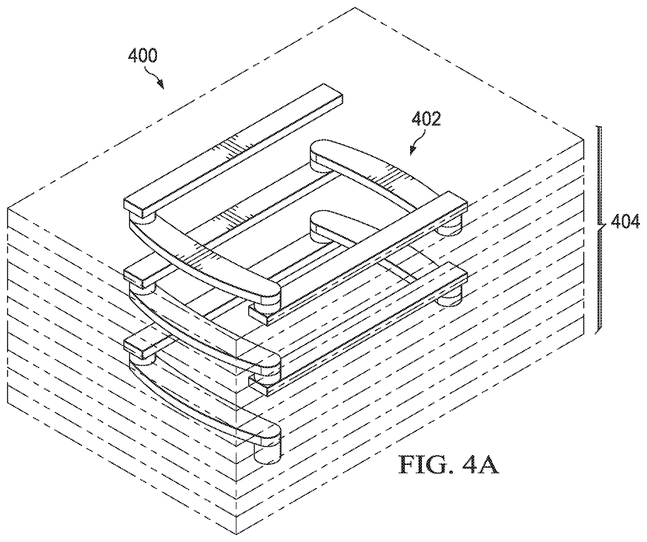

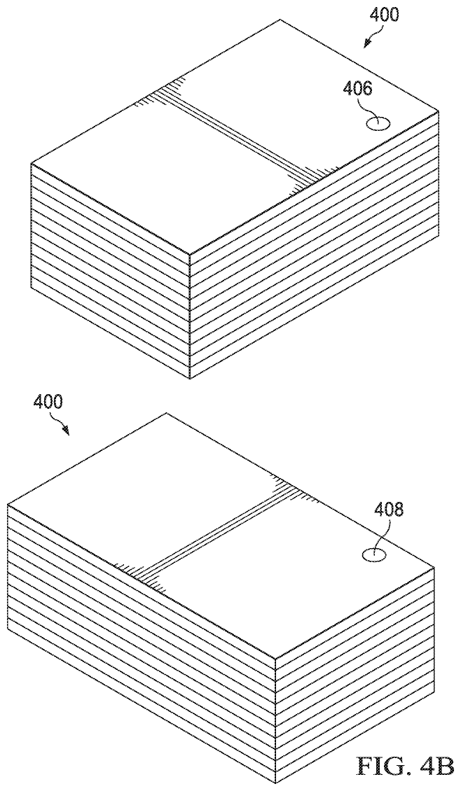

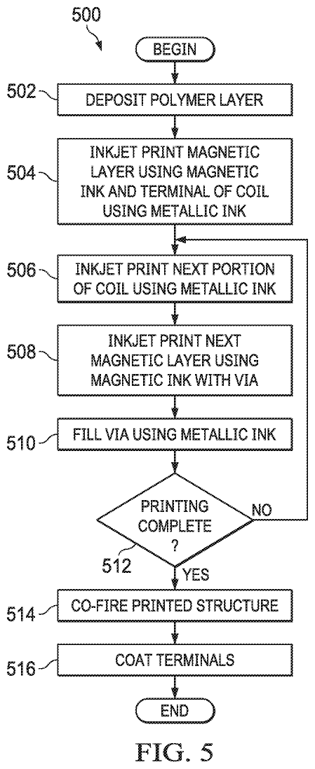

FIGS. 2A-2L depict the manufacture of an inkjet-printed coil device in a top-down view in accordance with various examples. FIGS. 3A-3L depict the manufacture of an inkjet-printed coil device in a modified side view in accordance with various examples. For clarity, the modified side view of FIGS. 3A-3L depicts all deposited portions of the coil at each stage of manufacture and is thus not a traditional side view. FIG. 5 depicts an example method 500 of manufacturing an inkjet-printed coil device in accordance with various examples. Accordingly, FIGS. 2A-2L, 3A-3L, and 5 are now described in parallel. The performance of the method 500, as depicted in FIG. 5 and as illustrated by the example structures of FIGS. 2A-2L and 3A-3L, is at least in part by the example inkjet printing system 100 of FIG. 1.

The method 500 begins by depositing a polymer layer 200—for example, a layer composed of polyamide (step 502). In an example, the polymer layer 200 is deposited (inkjet printed) using an ink housed within one of the reservoirs 112. To accomplish such printing of the polymer layer 200, the polymer ink may have particular characteristics, including a viscosity of approximately 30 mPa·s at room temperature and a surface tension of less than approximately 29 mN/m at room temperature. The viscosity affects the jetting capability of the ink, and the surface tension affects the wetting capability of the ink. In another example, the polymer layer 200 is deposited using an additive manufacturing system other than the system 100. In another example, the polymer layer 200 is formed and obtained from another source and is not deposited using additive manufacturing techniques. FIG. 2A depicts a top-down view of the polymer layer 200, and FIG. 3A depicts a side view of the polymer layer 200.

The method 500 continues by inkjet printing a magnetic layer using magnetic ink and a terminal of a coil using metallic ink (step 504). In an example, the magnetic layer—as with the remaining magnetic layers described below—is deposited (inkjet printed) using magnetic ink housed within one of the reservoirs 112. To accomplish such printing of the magnetic layer and one or more of the subsequent magnetic layers described below, the magnetic ink may have particular characteristics, including a particle size in the approximate range of tens of nanometers to hundreds of nanometers to obtain a viscosity of approximately 30 mPa·s at room temperature and a surface tension of less than approximately 29 mN/m. In examples, the magnetic ink particles include one or more of NiZn ferrite particles, MnZn ferrite particles, and NiCuZn ferrite particles to adjust the magnetic properties of the ink. FIG. 2B depicts a top-down view of the polymer layer 200 with a magnetic layer 202 abutting and supported by the polymer layer 200. In examples, the length-width area of the magnetic layer 202 is smaller than that of the polymer layer 200. In examples, the magnetic layer 202 is formed so that it includes a via (e.g., empty space extending completely through the thickness of the magnetic layer 202 to the polymer layer 200). The via may be filled with metallic ink to form a metallic layer 203 simultaneous with the printing of the magnetic layer 202, or after the printing of the magnetic layer 202. In other examples, metallic ink in metallic layer 203 is deposited prior to deposition of the magnetic layer 202 such that no via is formed at all. Other deposition techniques are contemplated and, in general, the metallic and magnetic inks may be deposited in any suitable manner to produce the structure depicted in FIG. 2B. In the event that a via is formed, it may be of any suitable shape and size. FIG. 3B depicts a side view of the metallic layer 203 filling the via and extending through the thickness of the magnetic layer 202.

To accomplish printing of the metallic layer 203 and one or more of the subsequent metallic layers described below, the metallic ink may have particular characteristics, including a particle size in the approximate range of tens of nanometers to hundreds of nanometers to obtain a viscosity of approximately 30 mPa·s at room temperature and a surface tension less than approximately 29 mN/m. In examples, the metallic ink particles include one or more of silver (Ag), copper (Cu), and palladium (Pd) particles to adjust the conductivity of the ink.

The method 500 continues by inkjet printing the next portion of the coil using metallic ink (step 506). As FIG. 2C depicts, a portion 204 of the coil is inkjet printed using metallic ink. As mentioned above, the coil portion 204, like all coil portions herein, may be referred to as metallic layers. The coil portion 204 is of any suitable shape and size, although in examples, the shape is curvilinear to facilitate the production of a coiled structure. The coil portion 204 is abutting and thus in electrical contact with the metallic layer 203. Because the metallic layer 203 extends through the magnetic layer 202 to reach the polymer layer 200, when the polymer layer 200 is later removed during a co-firing process, the metallic layer 203 is exposed on an outer surface of the magnetic layer 202 and thus forms a terminal to establish electrical contact between the coil and other circuitry. As FIG. 3C shows, the coil portion 204 abuts the metallic layer 203; the coil portion 204 abuts the magnetic layer 202; the metallic layer 203 abuts the magnetic layer 202 and the polymer layer 200; and the magnetic layer 202 abuts the polymer layer 200.

The method 500 continues by inkjet printing a next magnetic layer using magnetic ink, where the magnetic layer includes a via (step 508). FIG. 2D depicts the deposition of the magnetic layer 206 with a via 208. As FIG. 3D shows, the magnetic layer 206 abuts the magnetic layer 202 and the coil portion 204. The via 208 is positioned above the coil portion 204 so that when metallic ink is subsequently deposited to fill the via 208, such metallic ink abuts and electrically contacts the coil portion 204. Next, the method 500 comprises filling the via 208 using metallic ink (step 510). FIGS. 2E and 3E show metallic ink forming a metallic layer 210 filling the via 208 of FIGS. 2D and 3D. The metallic layer 210 abuts the magnetic layer 206 and the coil portion 204. The metallic layer 210 is in electrical contact with the metallic layer 203 via coil portion 204.

FIGS. 2D, 2E, 3D and 3E, along with steps 508 and 510, depict a two-step process in which a via is formed and is subsequently filled with metallic ink. However, as described above with respect to FIGS. 2B, 3B and step 504, it is also possible to simultaneously print the magnetic layer and metallic filling, and it is further possible to deposit the metallic ink prior to formation of the magnetic layer. The remainder of the drawings and discussion assume the formation and subsequent filling of a via, but the scope of disclosure is not limited as such, and any suitable deposition technique or sequence may be used to form one or more of the features depicted in the drawings.

The method 500 then determines whether the printing process is complete, that is, whether the coil has been fully formed (step 512). Assuming the printing process is not complete, the steps 506, 508, and 510 repeat in an iterative loop until the printing process is complete (step 512). FIGS. 2F-2L and 3F-3L depict example structures resulting from such iterations and are now briefly described.

FIG. 2F depicts the deposition of another coil portion 212 using metallic ink (step 506). The coil portion 212 is depicted as being rectangular, but, as with most or all other features described herein, may be formed in different shapes and sizes, depending on the application. Similarly, although the example coil being formed is ovaloid in shape, other shapes (e.g., traditional circular coils) are contemplated and fall within the scope of this disclosure. As FIG. 3F shows, the coil portion 212 abuts the metallic layer 210 and the magnetic layer 206. Thus, the coil portion 212 is in electrical contact with metallic layer 203.

FIG. 2G depicts the deposition of another magnetic layer 214 using magnetic ink (step 508). The magnetic layer 214 includes a via 216 that extends through the thickness of the magnetic layer 214. FIG. 3G shows the magnetic layer 214 abutting the coil portion 212 and the magnetic layer 206. FIG. 3G also shows the via 216 extending through the magnetic layer 214.

FIG. 2H shows the via 216 filled with metallic ink to form a metallic layer 218 (step 510). FIG. 3H shows a side view of the metallic layer 218, which abuts the magnetic layer 214 and the coil portion 212. An electrical connection is thus formed between the metallic layer 218 and the metallic layer 203 through the intervening metallic layers and coil portions.

FIG. 2I depicts the deposition of another coil portion 220 (step 506), which may be similar in shape and size to the coil portion 204. FIG. 3I shows the coil portion 220 abutting the metallic layer 218 and the magnetic layer 214.

FIG. 2J depicts the deposition of another magnetic layer 222 with a via 224 (step 508). FIG. 3J shows the magnetic layer 222 abutting the magnetic layer 214 and the coil portion 220.

FIG. 2K depicts the deposition of metallic ink in the via 224 to form a metallic layer 226 (step 510). FIG. 3K shows the metallic layer 226 abutting the coil portion 220 and the magnetic layer 222.

FIG. 2L depicts the deposition of a coil portion 228 (step 506), which may be similar in shape and size to the coil portion 212. FIG. 3L shows the coil portion 228 abutting the magnetic layer 222 and the metallic layer 226.

The iterative process of steps 506, 508, and 510 continues in this manner until the coil is fully formed (e.g., until the iterative process has been performed a predetermined number of times according to the manner in which the computer-executable code 106 is programmed). When the final via is filled with metallic ink to form a metallic layer, that metallic layer is similar to the metallic layer 203 in that it is exposed on an external surface of a magnetic layer and thus serves as a terminal via which the coil may electrically couple to external circuitry. When the printing is complete (step 512), the method 500 comprises co-firing the inkjet-printed structure (step 514), at which step the polymer layer 200 disintegrates. The method 500 also includes coating the terminals with an appropriate material, such as silver (step 516).

FIGS. 4A-4B depict multiple perspective views of an inkjet-printed coil device 400 in accordance with various examples. The device 400 may be formed as described above with respect to FIGS. 2A-2L, 3A-3L, and 5. FIG. 4A shows the device 400 having a fully formed, three-dimensional coil 402 (e.g., composed of various metallic layers, including the aforementioned coil portions) abutting a collection of magnetic layers 404. Described in another way, the coil device 400 comprises a collection of magnetic ink residue. The coil device 400 also includes a coil that is composed of metallic ink residue and that is encased within the collection of magnetic ink residue. FIG. 4A provides an interior view of the coil device 400, as ordinarily the coil 402 is hidden within the magnetic layers 404. The core along the longitudinal axis of the coil 402 is filled with magnetic ink, as depicted in, e.g., FIGS. 2B-2L and 4B. FIG. 4B shows the terminals 406, 408, which are metallic layers exposed on opposing, external surfaces of the coil device 400 (e.g., external surfaces of magnetic layers within the coil device 400). The terminals 406, 408 provide external electrical access to the coil 402 within the coil device 400.

Still referring to FIG. 3L, as shown, magnetic layer 202 is co-planar with metallic layer 203; coil portion 204 and metallic layer 210 are co-planar with magnetic layer 206; coil portion 212 and metallic layer 218 are co-planar with magnetic layer 214; and coil portion 220 and metallic layer 226 are co-planar with magnetic layer 222.

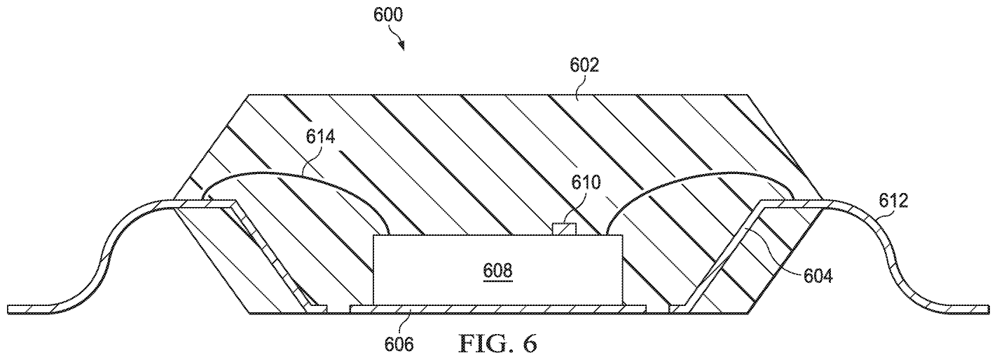

FIG. 6 depicts an inkjet-printed coil device mounted on an integrated circuit in a package. Specifically, FIG. 6 depicts a package 600 comprising a mold compound 602 that encases a lead frame 604. The lead frame 604 includes a die pad 606 on which a die 608 is mounted. The die 608 has an integrated circuit formed thereupon, and the integrated circuit may include an inkjet-printed coil device 600. The inkjet-printed coil device 600 may be fabricated using any or all of the techniques described herein. The inkjet-printed coil device 600 may be replaced with an inkjet-printed electronic component of any type that is fabricated using any or all of the techniques described herein. The die 608 couples to leads 612 via wire bonds 614. Thus, an electrical connection is formed between one or more of the leads 612 and the device 610.

In the foregoing discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection or through an indirect connection via other devices and connections. Similarly, a device that is coupled between a first component or location and a second component or location may be through a direct connection or through an indirect connection via other devices and connections. An element or feature that is “configured to” perform a task or function may be configured (e.g., programmed or structurally designed) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof. Additionally, uses of the phrases “ground” or similar in the foregoing discussion are intended to include a chassis ground, an Earth ground, a floating ground, a virtual ground, a digital ground, a common ground, and/or any other form of ground connection applicable to, or suitable for, the teachings of the present disclosure. Unless otherwise stated, “about,” “approximately,” or “substantially” preceding a value means+/−10 percent of the stated value.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

What is claimed is:

1. A device, comprising:
a plurality of magnetic layers comprising magnetic ink residue; and
a plurality of metallic layers comprising metallic ink residue and coupled to the plurality of magnetic layers, the plurality of metallic layers coupled to each other to form a coil.

2. The device of claim 1, wherein the device comprises an inductor.

3. The device of claim 1, wherein at least one of the plurality of metallic layers includes a terminal exposed on an outer surface of one of the plurality of magnetic layers.

4. The device of claim 3, wherein the terminal is coated with silver.

5. The device of claim 1, wherein the ends of the coil comprise terminals that are exposed on outer surfaces of two of the plurality of magnetic layers.

6. The device of claim 1, wherein the coil is a three-dimensional structure.

7. A method of fabricating a device, comprising:
inkjet printing a first magnetic layer using magnetic ink;
inkjet printing a first metallic layer using metallic ink, the first magnetic and metallic layers abutting each other;
inkjet printing a second magnetic layer using the magnetic ink, the first and second magnetic layers abutting each other; and
inkjet printing a second metallic layer using the metallic ink, the first and second metallic layers abutting each other, and the second magnetic and metallic layers abutting each other,
wherein the first and second metallic layers form at least part of a coil.

8. The method of claim 7, wherein the first magnetic and metallic layers are at least partially co-planar.

9. The method of claim 7, wherein the first magnetic and metallic layers are printed simultaneously.

10. The method of claim 7, wherein the first magnetic and metallic layers are printed sequentially.

11. The method of claim 7, further comprising providing a polymer layer and inkjet printing the first magnetic layer on the polymer layer.

12. The method of claim 7, further comprising co-firing the first and second magnetic and metallic layers.

13. The method of claim 12, further comprising coating terminals of the coil using silver after the co-firing.

14. The method of claim 7, wherein the coil is a three-dimensional structure.

15. A device, comprising:
a collection of magnetic ink residue; and
a coil encased within the collection of magnetic ink residue and comprising metallic ink residue, a first terminal of the coil exposed on a first surface of the collection of magnetic ink residue and a second terminal of the coil exposed on a second surface of the collection of magnetic ink residue.

16. The device of claim 15, wherein the first and second terminals are coated with silver.

17. The device of claim 15, wherein the device comprises a polymer layer abutting the collection of magnetic ink residue.

18. The device of claim 15, wherein the device is an inductor.

19. The device of claim 15, wherein the coil is a three-dimensional structure.

20. The device of claim 15, wherein at least some of the collection of the magnetic ink residue is positioned along an axis passing through a length of the coil.
